(19) United States
(12) Patent Application Publication
(10) Pub. No.: US 2012/0222722 A1
(43) Pub. Date: Sep. 6, 2012

(54) WINDOW

(75) Inventors: Itay Baruchi, Tel Aviv (IL); Moshe Ben Chorin, Rehovot (IL); Barak Freedman, Binyamina (IL); Alon Naim, Rosh-Haain (IL); Izhar Halahmi, Hod Hasharon (IL)

(73) Assignee: PYTHAGORAS SOLAR INC., Wilmington, DE (US)

(21) Appl. No.: 13/503,250

(22) PCT Filed: Oct. 21, 2010
(86) PCT No.: PCT/IL10/00868

§ 371 Date: Apr. 20, 2012

Related U.S. Application Data
(60) Provisional application No. 61/253,568, filed on Oct. 21, 2009.
(60) Provisional application No. 61/304,884, filed on Feb. 16, 2010.

(51) Int. Cl. H01L 31/052; H01L 31/0232; H01L 31/024

(52) U.S. Cl. 136/246; 136/259

(57) ABSTRACT

A window is provided, comprising at least one exterior layers, one or more photovoltaic (PV) cells configured to convert a first portion of solar radiation impinging on the window to electrical energy, and at least one thermal conduit configured to draw heat from the PV cells. The thermal conduits are in conductive thermal communication with at least one of the PV cells with at least one of the exterior layer.

### FIELD OF THE INVENTION

This invention relates to solar windows configured to generate electricity, especially those using prismatic optics to concentrate impinging solar radiation.

### BACKGROUND OF THE INVENTION

It is well known that solar radiation can be utilized by various methods to produce useable energy. One method involves the use of a photovoltaic cell, which is configured to convert solar radiation to electricity. Solar radiation collectors are typically used to gather sunlight or other radiation and direct it toward a photovoltaic cell. Often, concentrators are provided in order to focus the radiation from an area to a photovoltaic cell which is smaller than the area.

Often, a plurality of photovoltaic cells is provided to form a single module. This module may be formed so as to have characteristics separate from energy production which make it useful as a construction element. For example, the module may allow some light to pass therethrough without being used for energy production. Such a module may be installed in a building and used as a window or skylight.

### SUMMARY OF THE INVENTION

According to one aspect of the present invention, there is provided a window comprising
at least one exterior layers;
one or more photovoltaic (PV) cells configured to convert a first portion of solar radiation impinging on the window to electrical energy; and
at least one thermal conduit configured to draw heat from the PV cells;
   wherein the thermal conduits are in conductive thermal communication with at least one of the PV cells and with at least one of the exterior layer. This permits some solar radiation to pass through the window, while the heat from the PV cells may radiated outside keeping the room cool or, if desired, radiated into the room, providing a source of heat.

The thermal conduit may have a substantially L-shaped cross-section comprising a cell- contacting portion, constituting a first leg of the “L”, in conductive thermal communication with the PV cell, and a front-contacting portion, constituting a second leg of the “L”, in conductive thermal communication with the front layer.

The front layer may constitute one of the exterior layers and have a front-facing surface configured to be impinged upon by the first portion of solar radiation, wherein the front layer is in conductive thermal communication with the thermal conduit.

The window may comprise a rear layer constituting one of the exterior layers, wherein the rear layer is in conductive thermal communication with the thermal conduit.

The window may be configured to allow a second portion of solar radiation impinging on the window, being separate from the first portion, to pass therethrough.

The window may be configured to concentrate the first portion of solar radiation towards the PV cells.

The window may further comprise a plurality of solar units each comprising one or more of the PV cells and a concentrator configured to concentrate solar radiation toward the PV cell using total internal reflection. The first portion of impinging solar radiation may comprise radiation impinging within an acceptance angle of the concentrators. The solar unit may each further comprise an imaging prism configured to rectify solar radiation not concentrated toward the PV. The concentrator and the imaging prism may be congruent transparent prisms.

The thermal conduit may comprise a sealed hollow inner portion containing a filler material configured to undergo a phase change at a temperature which is above ambient temperature and below a temperature within a working range of the window.

The filler material may be a phase change material configured to melt at the temperature above ambient temperature and below the temperature within a working range of the window.

The filler material may be a fluid configured to vaporize at the temperature above ambient temperature and below the temperature within a working range of the window. The window may further comprise a cooling mechanism configured to absorb heat from the vaporized fluid sufficient to condense it. The cooling mechanism may be disposed above the hollow inner portion. Alternatively, the cooling mechanism may be disposed below the hollow inner portion, the window further comprising a mechanism, such as a capillary system, to carry the condensed fluid to the hollow inner portion. The hollow inner portion may be at least partially evacuated of air or pressurized.

The thermal conduit may be further configured to draw heat from the PV cell toward a side element disposed at the periphery of the window.

The window may further comprise a thermal paste applied between the PV cells and the thermal conduit.

The window may further comprise a rear pane spaced from the PV cells.

The window may further comprise an auxiliary pane disposed between the PV cells and the rear pane and being spaced from both. A rear-facing surface of the auxiliary pane may be provided with a low-emissivity coating. A low-emissivity coating may be provided on a front-facing surface of the rear pane. The low-emissivity coating may reflect a majority of radiation in to the infrared spectrum, and allows a majority of radiation in the visible spectrum to pass therethrough. Spaces between panes and other elements of the window may be filled with an inert gas or evacuated.

According to another aspect of the present invention, there is provided a window comprising a solar layer comprising a plurality of solar units configured to concentrate light impinging thereupon within an acceptance angle toward a photovoltaic (PV) cell; wherein at least some of the solar units are spaced from each other giving rise to gaps free of concentrating optics.

Diffusers may be provided within the gaps.

The window may further comprise a front pane disposed adjacent a solar-radiation surface of the solar layer. The diffusers may be separate from the front pane or formed thereon, for example by etching.

The window may further comprise a rear pane, wherein the rear pane is configured to disuse radiation passing therethrough.

One or more solar collectors, for example PV cells, may be provided in the gaps.

According to a further aspect of the present invention, there is provided a window comprising a solar layer comprising a plurality of solar units, each of the solar units comprising a concentrator and a photovoltaic (PV) cell, the concentrator being configured to concentrate solar radiation impinging thereupon within an acceptance angle toward the PV cell, wherein the concentrator is comprised to allow at least of portion of the solar radiation impinging within the acceptance angle to exit to solar unit without impinging on the PV cell.

The concentrator may be a prismatic concentrator configured to totally internally reflect radiation impinging thereon within the acceptance angle toward the PV cell off of a reflection plane thereof, the reflection plane being formed with one or more optical apertures configured to allow the portion to exit the concentrator thereby. The optical aperture may be formed as a saw-tooth. The profile of the saw-tooth may change along the length of the reflection plane.

The concentrator may comprise a receiver plane toward which all concentrated solar radiation is directed, the PV cell being smaller that the receiver plane.

The concentrator may comprise two receiver planes and be configured such that all concentrated solar radiation is directed toward one of the receiver planes, wherein the PV cell is provided at only one of the receiver planes.

According to a still further aspect of the present invention, there is provided a solar unit comprising:
a prismatic concentrator configured to concentrate light impinging thereon within an acceptance angle; and
an imaging prism configured to rectify light impinging on the concentrator outside of the acceptance angle,
   the concentrator and imaging prism being disposed such that a plane of each one faces that of the other and is spaced therefrom, wherein the faces are bonded to one another at ends thereof.

The concentrator may be a triangular prism comprising an entrance aperture, a reflection plane, and a receiver plane, the entrance aperture being configured for being impinged upon by solar radiation, and the reflection plane being configured for totally internally reflecting radiation impinging toward the receiver plane; the imaging prism being constructed equivalently to the concentrator, wherein the concentrator and imaging prism are disposed such that the reflection planes thereof face each other.

An optically clear adhesive is provided for the bonding. The adhesive may be selected from the group including UV/visible curable adhesive, pressure-sensitive adhesive, and silicone-based adhesive.

Ends of the faces may be welded together.

The concentrator and imaging prism may be manufactured as a single unit.

According to a still further aspect of the present invention, there is provided a method for manufacturing a prismatic solar concentrator and an imaging prism for use therewith, the method comprising:
providing a rectangular prism;
cutting the prism along a diagonal thereof.

The cutting may be performed by a laser, such as a CO₂ laser.

The cutting may comprise making cuts beginning at opposite corners and performing the cutting until the cuts meet.

According to a still further aspect of the present invention, there is provided a method of manufacture of a window, the method comprising:
providing a mold made of a first optical material, the mold having a shape of at least part of the window and comprising cavities;
completely filling the cavities with a second optical material; and
curing the second optical material.

The method may further comprise attaching photovoltaic cells to the mold.

Herein the specification and claims, the term “conductive thermal communication” indicates that two elements are in thermal communication with one another by contact, without requiring a third element to thermally connect them. It will be appreciated that use of a substance known to increase thermal communication, including a thermal paste, should not be considered a third element, and two elements in thermal communication with each other via such a substance, which would still be in conductive thermal communication in the absence of the substance, are considered to be in conductive thermal communication.

Herein the specification and claims, the term “geometrically prismatic” refers to an element formed as a polyhedron with two polygonal faces lying in parallel planes and with the other faces parallelograms.

### BRIEF DESCRIPTION OF THE DRAWINGS

In order to understand the invention and to see how it may be carried out in practice, embodiments will now be described, by way of non-limiting examples only, with reference to the accompanying drawings, in which:

FIGS. 1A and 1B are cross-sectional views of examples of a window according to the present invention;

FIG. 2 are graphs designed to assist in selecting parameters of the windows illustrated in FIGS. 1A and 1B;

FIGS. 3A through 5 are cross-sectional views of a concentrator and PV cell of the windows illustrated in FIGS. 1A and 1B, with different examples of thermal conduits;

FIGS. 6A through 7C are cross-sectional views of modifications of the windows illustrated in FIGS. 1A and 1B;

FIGS. 8 and 9B are cross-sectional views of modifications of a concentrator according to the present invention;

FIG. 9A is a cross-sectional view of a concentrator with a modified PV cell according to the present invention;

FIG. 10 is a cross-sectional view illustrating a concentrator and imaging prism of the windows illustrated in FIGS. 1A and 1B, bonded to one another according to a modification of the present invention;

FIGS. 11A and 11B are cross-sectional views of a rectangular prism during examples of manufacture of the concentrator and imaging prism of the windows illustrated in FIGS. 1A and 1B;

FIG. 12A illustrates a mold for use in manufacturing the window illustrated in FIGS. 1A and 1B;

FIG. 12B illustrates pieces which may be used to construct the mold; and

FIG. 12C illustrates a window manufactured using the mold illustrated in FIG. 12A.

### DETAILED DESCRIPTION OF EMBODIMENTS

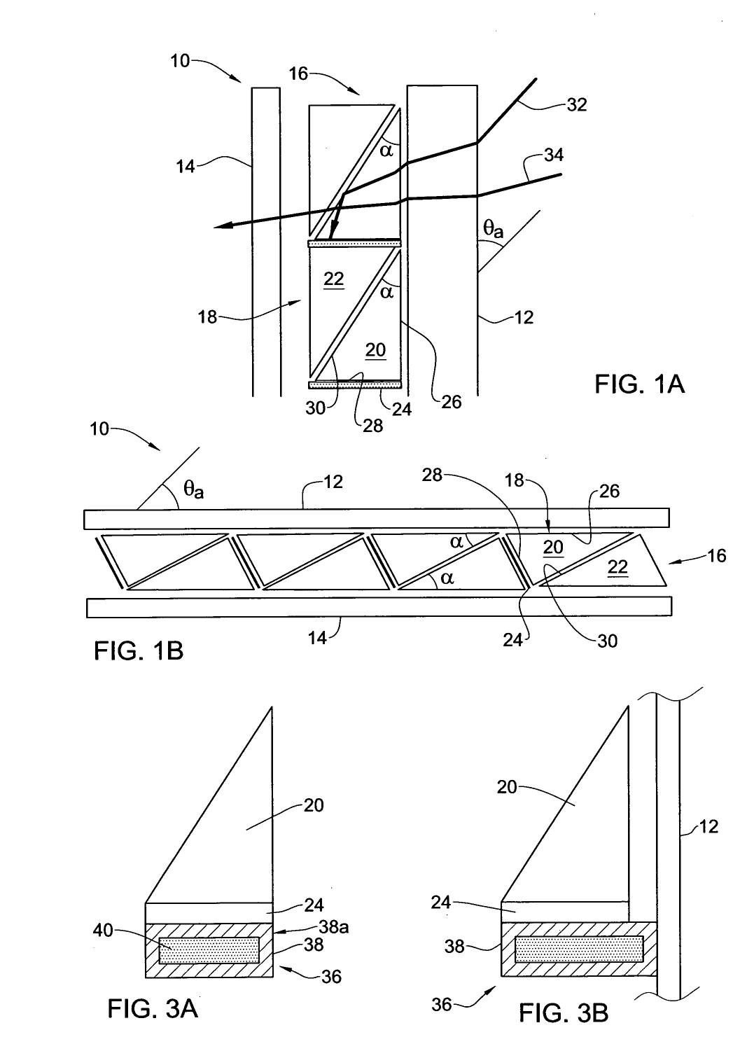

As illustrated in FIGS. 1A and 1B, there is provided a photovoltaic (PV) window, which is generally indicated at 10. The window 10 comprises a front pane 12 constituting a first exterior layer of the window, an optional rear pane 14 constituting a second exterior layer of the window, and a PV layer 16. The window 10 may be designed for mounting vertically or horizontally, as illustrated, or in any other suitable disposition. It will be appreciated by one skilled in the art the necessary design parameters to apply to any given design based on the description presented hereinbelow.

The window 10, and specifically the PV layer 16 thereof, is designed so as to utilize solar radiation impinging on the front pane 12 at an angle within an acceptance angle θₐ for generation of electricity, and to allow passage therethrough of solar radiation impinging on the front pane 12 at an angle outside the acceptance angle. As will be described, the acceptance angle θₐ is calculated as a function of material and constructional properties of the PV layer 16.

The rear pane 14 may be configured to diffuse radiation passing therethrough, thereby providing more uniform illumination using light impinging on the window 10 at an angle outside the acceptance angle θₐ.

The PV layer 16 comprises a plurality of PV units 18, arranged adjacent one another. Each PV unit 18 comprises a concentrator 20, an optional imaging prism 22 made from a material having the same optical properties as the concentrator, and a PV cell 24, which is designed to convert impinging solar radiation into electricity. The imaging prism 22 may be spaced slightly from the concentrator 20, for example by a small air gap.

The concentrator 20 may be provided as a right-triangular prism, for example made out of PMMA or another transparent optical plastic such as polycarbonate) being characterized by prism angle α. It is designed to concentrate solar radiation that impinges on an entrance aperture 26 thereof within the acceptance angle θₐ, toward a receiver plane 28 via total internal reflection off of a reflection plane 30 and, optionally, the interior surface of the receiver plane. The PV cell 24 is disposed at the receiver plane 28, thereby exposing it to concentrated solar radiation. For a required acceptance angle, which may be determined based on the location in which the window 10 is to be installed, the prism angle α is given as:

$$α = {θ}_{a} - {sin}^{- 1} ( \frac{cos {θ}_{a}}{n} ) = {sin}^{- 1} ( \frac{1}{n} ) {θ}_{a} - {sin}^{- 1} ( \frac{cos {θ}_{a}}{n} )$$

where n is the refractive index of the material of the concentrator 20. The above formula assumes that the refractive index of the concentrator is the same as that of the front pane 12 and any adhesion layer therebetween.

As mentioned above, light which impinges on the window 10 within the acceptance angle θₐ, for example along the path designated by 32, is reflected within the concentrator 20 toward the PV cell 24. Light which impinges on the window 10 outside the acceptance angle θₐ, for example along the path designated by 34, exits the concentrator 20 via the reflection plane 30. It will be appreciated that the concentrator 20 distorts the image as light passes therethrough. Therefore, the imaging prism 22 is provided to rectify the image, thereby allowing the window 10 to be used as a transparent window. For applications where a transparent window is not necessary or undesired, for example as a skylight wherein the main function is transmission therethrough of light for illumination of the room, the imaging prism 22 may be left out.

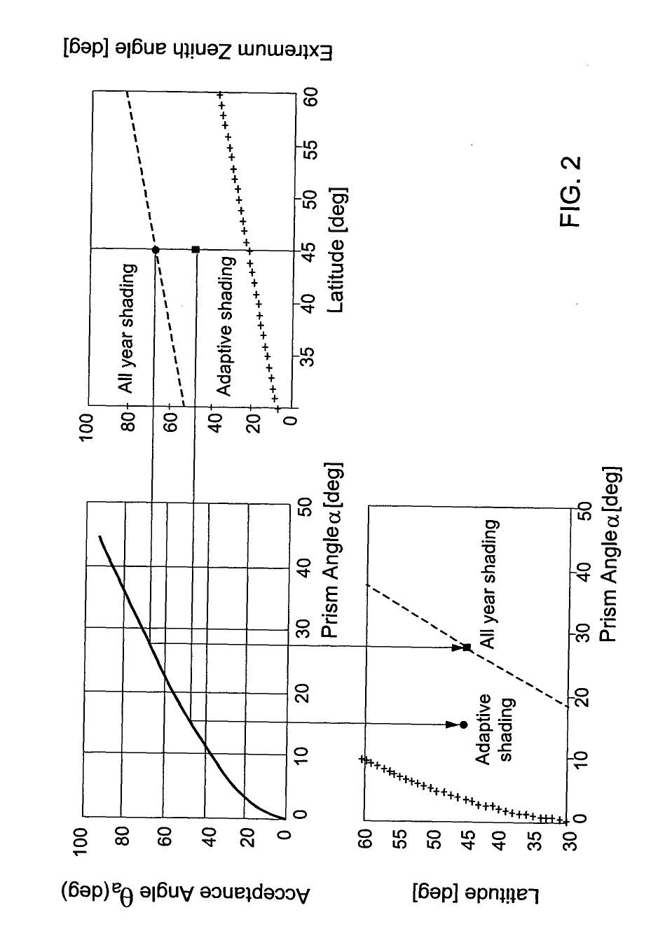

FIG. 2 provides an example of how an appropriate acceptance angle θₐ may be selected. Based on the latitude at which the window 10 will be installed, the maximum zenith angle (i.e., the largest angle from the vertical which the sun will make over the course of the year) is found. If “all year shading” is desired, i.e., if no direct sunlight should be admitted via the window, the acceptance angle θₐ should be chosen to be equal to the extreme zenith angle (bearing in mind that sunlight impinging within the acceptance angle is accepted by the PV cell 24, and does not pass through the window). If “adaptive shading” is desired, i.e., if direct sunlight should be admitted only when the sun is at lower elevations, for example during the winter or morning and afternoons/evening during the summer, the acceptance angle θₐ should be chosen to be somewhat lower than the extreme zenith angle. In such a case, the lower the acceptance angle, the more sunlight will be admitted via the window 10.

By designing the concentrator 20 appropriately, the amount of heat entering a room can be controlled. The acceptance angle θₐ may be selected such that all sunlight during the summer, or at least during the hottest part of the day, is reflected within the concentrator 20 toward the PV cell 24, thus reducing the solar heat load within the room, and all sunlight during the winter exits via the reflecting surface 30, thus increasing the solar heat load within the room. This arrangement will reduce the amount of cooling required during the summer, and decrease the amount of heating required during the winter, saving energy all year.

During use, some of the solar radiation which reaches the PV cell 24 is converted into electrical energy. However, a non-significant amount is converted into heat, raising the temperature of the cell 24. Depending on the design thereof, dependent on, inter alia, its construction and the materials it comprises, the concentrator 20 may begin to undergo deformation at elevated temperatures, for example at temperatures above 90° C.-150° C. In addition, the efficiency of the PV cell 24 decreases with increasing temperature. Thus, the window may comprise one or more heat dissipation arrangements.

The heat dissipation arrangements comprise a thermal conduit, which is designated 36 in the accompanying figures, configured to draw heat from the PV cells 24. It may be configured to draw heat from the PV cells 24 toward the front and/or rear panes 12, 14 via conduction and radiate it to the adjacent environment. Alternatively or in addition, they may be configured to draw heat from the PV cells 24 toward one or more mullion (not illustrated) or other element spanning between the front and rear panes 12, 14 at a periphery of the window 10. As such, it is made of any appropriate thermally-conduction material, such as aluminum. In order to allow heat conduction over this relatively longer distance, the construction of the thermal conduit 36 may be specially adapted for this purpose.

For example, the thermal conduit 36 may be made of a solid material, such as aluminum or any other appropriate material, but constructed thicker than it would be if it would be in thermal communication with the front pane 12. However, such an arrangement may impede the view through the window.

Alternatively, the thermal conduit 36 may comprise a main portion being geometrically prismatic and in conductive thermal communication with the PV cells 24, and an auxiliary portion. The auxiliary portion is distinct from the main portion, i.e., there is a clear and evident boundary between them, even if they constitute parts of a single solid element. For example, the main and auxiliary portions do not together constitute a single geometrically prismatic element. The auxiliary is configured to increase the thermal conductivity of the thermal conduit 36 in such a way that the overall thickness thereof is less than that which would be required of the main portion to provide the same thermal conductivity in the absence of the auxiliary portion.

For example, as illustrated in FIG. 3A, the thermal conduit 36 may comprise a hollow outer shell 38, at least the PV-contacting portion 38a thereof constituting the main portion, made of a conducting material, and an inner core 40, constituting the auxiliary portion, made of a phase-change material (PCM). The PCM has a melting point which is below that at which the PV cell 24 begins to deform, and above normal ambient temperatures. Thus, during heating of the cell 24, the PCM core 40 is heated to its melting point, at which point it absorbs additional heat as latent heat (heat of transformation) while still remaining solid. Thus, the use of a PCM allows a greater amount of heat to be drawn from the cell 24 without undergoing a corresponding increase in temperature itself. This allows the thermal conduit 36 to increase the rate at which it draws heat from the PV cell 24, thereby facilitating a greater efficiency of cooling of the cell 24 than would be possible by providing a similarly-constructed inner core made of a material with a higher melting point, or a solid thermal conduit having the same exterior dimensions.

It will be appreciated that the thermal conduit 36 described with reference to FIG. 3A may be modified, as illustrated in FIG. 3B, by extending the shell 38 to contact the front pane 12, the rear pane 14, or both, in order to increase the rate at which the thermal conduit 36 draws heat from the PV cell 24 by dissipating some of the heat drawn directly into the outside environment and/or the room.

According to another example, as illustrated in FIG. 4A, the thermal conduit 36 is constituted by a heat pipe, comprising an optionally-rectangular tube 42, constituting the main portion, having a hollow 44 which, according to one modification thereof, is disposed at an upwardly-sloping angle along the length of the tube. This may be accomplished by providing a uniform tube 42 disposed at an angle in thermal communication with the PV cell 24, or by providing a tube 42 with a hollow 44 which slopes upwardly therewithin. A cooling mechanism (not illustrated) configured to draw heat from thermal conduit 36 is provided at the higher side of the hollow 44. A fluid 46, constituting the auxiliary portion, in liquid form is provided within the hollow 44 at a pressure at which it vaporizes at a temperature below that at which the PV cell 24 begins to deform, and above normal ambient temperature. The pressure may be higher or lower than ambient depending on the vaporization properties of the fluid 46 and desired temperature at which the PV cell 24 should be kept.

During heating of the cell 24, the fluid 46 is heated to its vaporization point, at which point it absorbs additional heat as latent heat (heat of transformation) while still remaining liquid. When the fluid vaporizes, fully or partially, the vapor rises to the cooling mechanism wherein it is cooled, thereby condensing. The condensed fluid 46 flows downwardly in the hollow 44 wherein the above repeats. This allows the thermal conduit 36 to increase the rate at which it draws heat from the PV cell 24, thereby facilitating a greater efficiency of cooling of the cell 24 than would be possible by providing a similarly-constructed hollow 44 filled with a material with a higher melting point, or a solid thermal conduit having the same exterior dimensions.

It will be appreciated that depending on the material used as the fluid 46 and the remainder of the contents of the hollow 44, the cooling mechanism may be provided at the lower end of the hollow, with a capillary system or other appropriate mechanism being provided to bring the condensed fluid 46 back toward the hollow.

It will be further appreciated that the thermal conduit 36 described with reference to FIG. 4A may be modified, as illustrated in FIG. 4B, by extending the tube 42 to contact the front pane 12, the rear pane 14, or both, in order to increase the rate at which the thermal conduit 36 draws heat from the PV cell 24 by dissipating some of the heat drawn directly into the outside environment and/or the room.

According to another example as illustrated in FIG. 5, an L-shaped thermal conduit 36 is provided to draw heat from the PV cell 24. The thermal conduit 36 according to this example comprises a cell-contacting portion 50 constituting the main portion and one of the legs of the “L” and being thermally bonded to the PV cell 24, and a pane-contacting wing 52 constituting the auxiliary portion and the other of the legs of the “L” and being thermally bonded to the front pane 12. Thus, heat is drawn from the PV cell 24 to the front pane 12, from where it is radiated into the outside atmosphere.

The window 10 may be provided with a printed circuit board (PCB) to electrically connect PV cells 24. The PCBs, which may be metal-core PCBs (MCPCBs), may further be configured to draw heat from the PCB, for example as disclosed in co-pending application PCT/IL2010/000817, filed Oct. 7, 2010, which is incorporated herein by reference. When such PCBs are provided, it will be appreciated that references to the PV cells 24 may refer as well to the PV cells 24 including their associated PCBs, without departing from the scope of the present invention, mutatis mutandis.

In addition to the above, the thermal conduit may be designed so as to provide mechanical support for the window 10 in general, and the elements of the PV layer 16 in particular.

It will be appreciated that although specific constructions of thermal conduits 36 were presented in connection with examples thereof in thermal communication with either the front pane 12 or mullions, it will be appreciated that any construction may be provided as part of a thermal conduit configured to draw heat from the PV cells 24 toward any one or more of the front pane 12, rear pane 14, and mullions, mutatis mutandis.

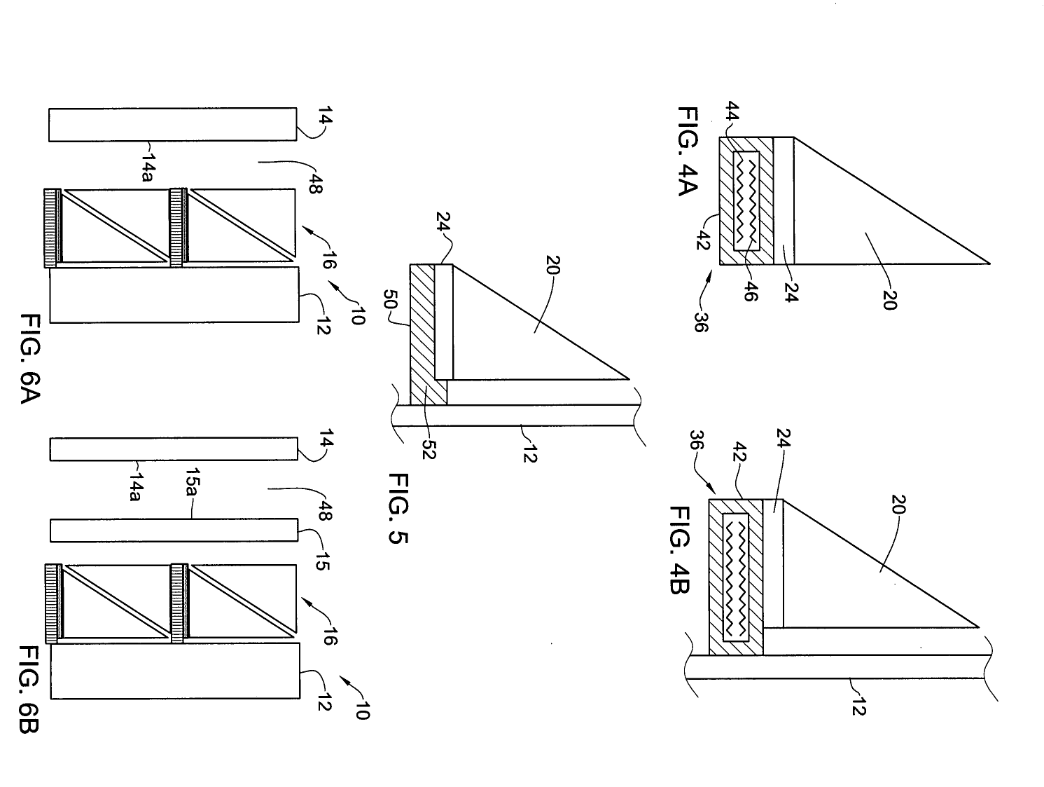

According to any of the above examples, when the window 10 comprises the rear pane 14, it should be thermally isolated from the PV layer 16 in order to prevent or limit the amount of heat entering the room. As illustrated in FIG. 6A, it may be spaced from the PV layer 16 by a gap 48, which may be between 1 mm and 14 mm, for example between 2 mm and 3 mm. The gap 48 may be evacuated or filled with an inert gas. A low-emissivity coating may be applied to a front-facing surface 14a of the rear pane 14, selected to reflect light in the infrared spectrum while allowing visible light to pass therethrough.

Alternatively, as illustrated in FIG. 6B, an auxiliary pane 15 may be provided between the PV layer 16 and the rear pane 14. The gap 48 between the rear and auxiliary panes 14, 15 may be evacuated or filled with an inert gas. The rear-facing surface 15a of the auxiliary pane 15 and/or the front-facing surface 14a of the rear pane 14 may be provided with a low-emissivity coating.

It will be further appreciated that examples wherein heat is radiated via the front pane 12 may be modified so as to conduct heat toward the rear pane 14 so as to radiate it into the room. This may be particularly advantageous in climates having a high amount of solar exposure, but are nonetheless relatively cold most of the year. In such an arrangement, the PV units 18 and/or the thermal conduits 36 may be arranged such that are in conductive thermal communication with the rear pane 14.

The window 10 may be designed so as to increase or decrease the amount of light entering the room therethrough. Depending on the orientation thereof, different amounts of diffuse light and reflected light will pass through the window as described with reference to FIGS. 1A and 1B. Therefore, other designs are provided to allow both diffuse and reflected light to pass.

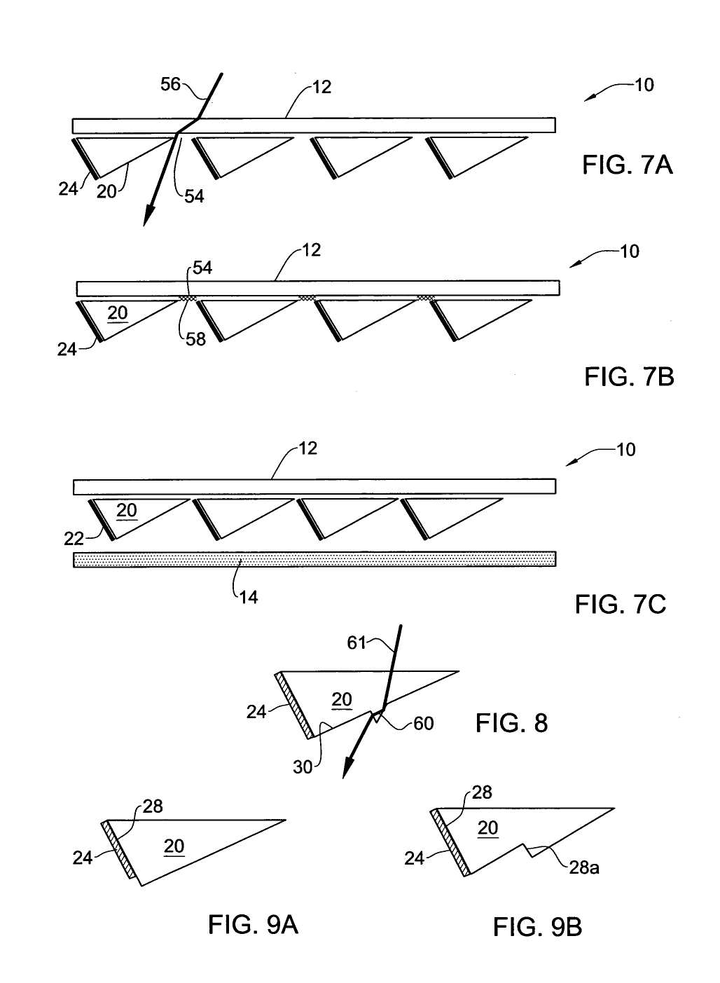

As illustrated in FIG. 7A, concentrators 20 may be spaced apart from one another, giving rise to gaps 54 therebetween. As illustrated, some of the solar radiation, indicated by arrow 56, impinging on the front pane 12 reaches the inner surface 12a thereof at a location free of concentrating optics, i.e., at a gap 54, and is thus free to enter the room.

As illustrated in FIG. 7B, diffusers 58 may be provided on the inner surface 14a of the front pane 14 in the gaps 54, in order to spread the light within the room. The diffusers 58 may be a separate element attached to the front pane 14, or an appropriate pattern etched thereon. Alternatively or additionally, i.e., whether or not gaps are provided between adjacent concentrators 20, as illustrated in FIG. 7C, the rear pane 14 may be configured to diffuse incoming radiation.

Alternatively, for example when less light is desired, the gaps 54 may be filled in with an opaque material, including, but not limited to, a photovoltaic cell or other solar collector, part of a mechanical support system, part of a heat or electrical conduction system, etc.

It will be appreciated that according to the examples described with reference to FIGS. 7A through 7C, the imaging prism 22 may be absent. This may be particularly useful in a case when only illumination is required, and rectification of non-concentrated radiation is therefore not necessary.

As illustrated in FIG. 8, the reflecting plane 30 may be provided with one or more saw- teeth 60 (only one is illustrated in FIG. 8), constituting an optical aperture, designed so as to allow at least some of the radiation impinging within the acceptance angle θₐ to exit the concentrator 20 via the reflecting pane, as indicated by arrow 61. Ray-tracing software may be used to determine the shape of the saw-teeth 60 to allow passage of radiation impinging within a desired range of angles. In addition, it will be appreciated that although the cross-section illustrated in FIG. 8 implies that the shape of the saw-tooth 60 is uniform along its length, it will be appreciated that it may have a three-dimensional geometry allowing passage therethrough of radiation depending on the east-west position of the sun. As illustrated in FIG. 9A, the PV cell 24 may be smaller than the receiver plane 28. Thus, any concentrated solar radiation impinging on the portion of the receiver plane 28 free of the PV cell 24 exits the window 10 and passes into the room. Similarly, as illustrated in FIG. 9B, the concentrator 20 may be formed with a “shelf”, giving rise to an auxiliary receiver plane 28a, parallel to the receiver plane 28, via which concentrated solar radiation exits.

The concentrator 20 and imaging prism 22 should be accurately positioned with respect to one another, such that the facing surfaces thereof are exactly parallel to one another with a small gap therebetween. Therefore, a rigid support bracket may be provided. A construction similar to the thermal conduit 36 described with reference to FIG. 5, may serve as the support brackets.

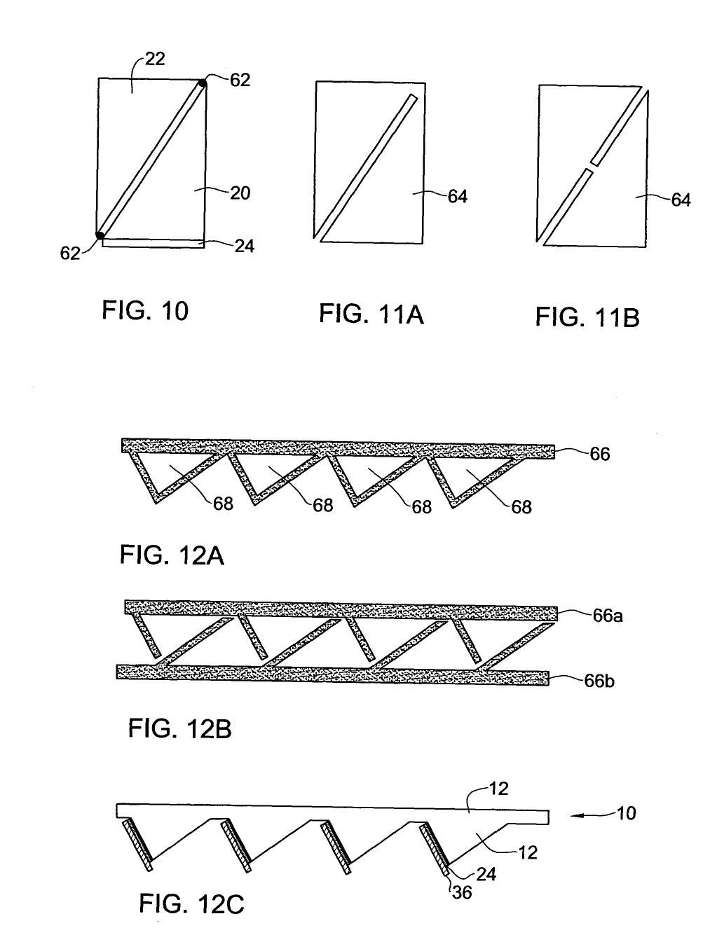

As illustrated in FIG. 10, the concentrator 20 an imaging prism 22 are spaced from one another by a small gap. In order to prevent liquids and other dirt to penetrate the gap, e.g., during manufacture, the edges of the facing surfaces may be bonded to one another, as indicated at 62. Besides the sealing provided thereby, this construction imparts an additional mechanical strength to the components of the window 10, as each concentrator 20 and each imaging prism 22 is mechanically connected to two support brackets (i.e., the support bracket carrying the concentrator 20 also carries the imaging prism 22 bonded thereto, and vice versa). The bonding may be accomplished by providing an optically clear adhesive, such as UV/visible curable adhesive, a pressure-sensitive adhesive, or a silicone-based adhesive. Alternatively, the concentrator 20 and imaging prism 22 may be joined, for example by welding, soldering, or by being manufactured as a single unit, for example by being co-molded or co-extruded with one another. The welding may be accomplished by any known means, including, but not limited to, heat welding, ultrasonic welding, vibrational welding, or chemical welding.

The concentrator 20 and imaging prism 22 may be made from a single rectangular prism. According to one example, as illustrated in FIGS. 11A and 11B, a rectangular prism 64 is provided. It is cut along its diagonal, for example by laser cutting, in particular by using a CO₂ laser. It may be cut from one end, as illustrated in FIG. 11A, or from both ends meeting in the middle, as illustrated in FIG. 11B.

As illustrated in FIG. 12A, the window 10 or parts thereof may be manufactured using a mold 66. The mold 66 may be formed in any convenient way, including, but not limited to, extrusion. It may be manufactured as a single piece, as illustrated in FIG. 12A, or as two separate pieces 66a, 66b, which are joined together.

The mold 66 is made of an optical material and comprises cavities 68. It will be appreciated that the term “optical material” as used herein the specification and claims refers to a material which is transparent to light, and is thus suitable for use in the window. Such material may include, but are not limited to, PMMA and polycarbonate,

The cavities 68 are completely filled with an optical material and then cured. The optical material may be an optical adhesive, silicone grease, silicone adhesive, or a UV curable adhesive such as the one disclosed in described WO 2010/055507 or WO 2010/055508, both to the present applicant, and the disclosures of which are both incorporated herein by reference.

Once cured, additional elements, such as PV cells 24 and thermal conduits 36, are added. In addition, PCBs or MCPCBs may be added, as described above. It will be appreciated that the elements may be added at any appropriate point during manufacture of the window, including before curing.

Using the above method, a relatively thin window 10, illustrated in FIG. 12C, can be produced. In such a window, the front pane 12 and concentrators 20 are integrally formed with one another. It will be appreciated that other elements, such as a rear pane, imaging prisms, etc., may be added to the window 10 illustrated in FIG. 12C.

Those skilled in the art to which this invention pertains will readily appreciate that numerous changes, variations and modifications can be made without departing from the scope of the invention mutatis mutandis.

1.-54. (canceled)

55. A window comprising:
at least one exterior layer;
one or more photovoltaic (PV) cells configured to convert a first portion of solar radiation impinging on the window to electrical energy; and
at least one thermal conduit configured to draw heat from the PV cells;
wherein the thermal conduits are in conductive thermal communication with at least one of the PV cells and with at least one of the exterior layer.

56. The window according to claim 55, wherein the thermal conduit has a substantially L-shaped cross-section comprising a cell-contacting portion, constituting a first leg of the “L”, in conductive thermal communication with the one or more PV cells, and a front-contacting portion, constituting a second leg of the “L”, in conductive thermal communication with the front layer.

57. The window according to claim 55, wherein the at least one exterior layer comprises a front layer having a front-facing surface configured to be impinged upon by the first portion of solar radiation, wherein the front layer is in conductive thermal communication with the thermal conduit.

58. The window according to claim 55, being configured to allow a second portion of solar radiation impinging on the window, being separate from the first portion, to pass therethrough.

59. The window according to claim 55, being configured to concentrate the first portion of solar radiation towards the one or more PV cells.

60. The window according to claim 55, further comprising a plurality of solar units each comprising one or more of the one or more PV cells and a concentrator configured to concentrate solar radiation toward the one or more PV cells using total internal reflection, wherein the first portion of impinging solar radiation comprises radiation impinging within an acceptance angle of the concentrators and wherein the solar unit each further comprise an imaging prism configured to rectify solar radiation not concentrated toward the one or more PV cells, and wherein the concentrator and imaging prism are congruent transparent prisms.

61. The window according to claim 55, wherein the thermal conduit comprises a sealed hollow inner portion containing a filler material configured to undergo a phase change at a temperature that is above ambient temperature and below a temperature within a working range of the window.

62. The window according to claim 61, wherein the filler material is a phase change material configured to melt at the temperature above the ambient temperature and below the temperature within the working range of the window.

63. The window according to claim 61, wherein the filler material is a fluid configured to vaporize at the temperature above the ambient temperature and below the temperature within the working range of the window.

64. The window according to claim 55 further comprising a metal core printed circuit board electrically connecting the PV cells, and configured to draw heat therefrom toward the exterior layer.

65. The window according to claim 55, further comprising a rear pane spaced from the one or more PV cells.

66. The window according to claim 65, further comprising an auxiliary pane disposed between the one or more PV cells and the rear pane and being spaced from both.

67. The window according to claim 66, wherein a rear-facing surface of the auxiliary pane is provided with a low-emissivity coating.

68. The window according to claim 65, further comprising a low-emissivity coating on a front-facing surface of the rear pane.

69. The window according to claim 67, wherein the low-emissivity coating reflects a majority of radiation in the infrared spectrum, and allows a majority of radiation in the visible spectrum to pass therethrough.

70. The window according claim 65, wherein spaces between the rear pane and other elements of the window are filled with an inert gas.

71. The window according to claim 65, wherein spaces between panes and other elements of the window are evacuated.

72. A window, comprising:
a solar layer comprising a plurality of solar units configured to concentrate light impinging thereupon within an acceptance angle toward a photovoltaic (PV) cell;
wherein at least some of the solar units are spaced from each other giving rise to gaps free of concentrating optics;
wherein a solar collector is provided in the gaps.

73. A solar unit comprising:
a prismatic concentrator configured to concentrate light impinging thereon within an acceptance angle; and
an imaging prism configured to rectify light impinging on the concentrator outside of the acceptance angle;
wherein the concentrator and the imaging prism are disposed such that a plane of each one faces that of the other and is spaced therefrom, wherein the faces are bonded to one another at ends thereof.

74. The solar unit according to claim 73, wherein ends of the faces are welded together.
